(19) United States
(12) Patent Application Publication
(10) Pub. No.: US 2009/0309177 A1
(43) Pub. Date: Dec. 17, 2009

(54) Wafer level camera module and method of manufacturing the same

(75) Inventors: Won Kyu Jeung, Seoul (KR); Seung Seoup Lee, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/285,943

(22) Filed: Oct. 16, 2008

(30) Foreign Application Priority Data
Jun. 17, 2008 (KR) 10-2008-0056789

(51) Int. Cl. H01L 31/18; H01L 31/0232

(52) U.S. Cl. 257/432; 438/65; 257/E31.127; 257/E21.499

(57) ABSTRACT

The present invention relates to a wafer level camera module and a method of manufacturing the same and provides a wafer level camera module including a wafer provided with an image sensor on a top surface; a transparent member bonded to the wafer through anodic bonding to seal the image sensor; a spacer bonded to the transparent member through the anodic bonding by including a window to expose the image sensor; and a wafer lens bonded to the spacer through the anodic bonding to cover the window of the spacer and further a method of manufacturing the same.

### CROSS-REFERENCE TO RELATED APPLICATIONS

This application claims the benefit of Korean Patent Application No. 10-2008-0056789 filed with the Korea Intellectual Property Office on Jun. 17, 2008, the disclosure of which is incorporated herein by reference.

### BACKGROUND OF THE INVENTION

1. Field of the Invention

The present invention relates to a wafer level camera module and a method of manufacturing the same; and, more particularly, to a wafer level camera module and a method of manufacturing the same to bond substrates through anodic bonding.

2. Description of the Related Art

Currently, a portable terminal such as a mobile phone and a PDA(Personal Digital Assistant) is used as multi-convergence for a music, a movie, a TV and a game as well as a simple call function with development of a technique thereof and the most representative one of things to lead development of the multi-convergence is a camera module. Such a camera module has been changed from existing 300 thousand pixels(VGA level) to high pixels of current more than 8 million pixels and has been changed to implement various additional functions such as AF(Auto-Focusing) and optical zoom.

In general, a CCM(Compact Cameral Module) is small and is applied to a diversity of IT(Information Technology) equipment such as a potable mobile communication device including a camera phone, a PDA and a smart phone and recently, the release of devices mounting small cameral modules according to various consumers' tastes has been gradually increasing.

The camera module has been manufactured by using an image sensor such as a CCD(Charge-Coupled Device) or a CMOS(Complementary Metal-Oxide Semiconductor) as a primary component. The camera module condenses an image of a subject through the image sensor and stores the image as data on a memory in equipment, wherein the stored data is displayed with a picture through a display medium such as an LCD(Liquid Crystal Display) monitor or a PC(Personal Computer) monitor in the equipment.

A general packaging method of the image sensor for the camera module includes a flip chip method(COF; Chip Of Flexible), a wire bonding method(COB: Chip Of Board) and a CSP(Chip Scale Package) method, and so on. Among these methods, the COF method and the COB method have been widely used.

Recently, a WLCM(Wafer Level Camera Module) has been suggested to maximize reduction of a cost.

The WLCM is appropriate to mass production by manufacturing an image sensor and a lens by a wafer level method and is constructed to be directly mounted on a main substrate of a mobile phone.

The conventional WLCM is produced by adhering a lens wafer onto an image sensor wafer by a bonding method, manufacturing a unit module through a dicing process, and then coupling an optical case with an opening to open only an incident hole of the lens.

However, conventionally, an adhesive was used to assemble a wafer level package of the image sensor and a lens group, which increases an error due to a thickness of an adhesion layer and thus it is difficult to obtain a high quality image and it is almost impossible to apply it to an effective mass production process.

### SUMMARY OF THE INVENTION

The present invention has been invented in order to overcome the above-described problems, it is, therefore, an object of the present invention to provide a wafer level camera module and a method of manufacturing the same capable of securing an exact position error in a wafer level, facilitating mass production and reducing material and process costs by bonding substrates through anodic bonding.

In accordance with an embodiment of the present invention to achieve the object, there is provided a wafer level camera module including a wafer provided with an image sensor on a top surface; a transparent member bonded to the wafer through anodic bonding to seal the image sensor; a spacer bonded to the transparent member through the anodic bonding by including a window to expose the image sensor; and a wafer lens bonded to the spacer through the anodic bonding to cover the window of the spacer.

Herein, the wafer may be made of silicon or material containing the silicon and the transparent member may be made of material containing an alkali metal such as glass.

Further, the spacer may be made of the silicon or material containing the silicon and the wafer lens may be made of the material containing the alkali metal such as the glass.

And, in accordance with another embodiment of the present invention to achieve the object, there is provided a method of manufacturing a wafer level camera module including the steps of: manufacturing a wafer level package by bonding a transparent member for sealing image sensors to an upper part of a wafer provided with the image sensors on a top surface through anodic bonding; positioning a spacer provided with windows to expose the image sensors on an upper part of the waver level package; positioning a wafer lens on an upper part of the spacer; bonding the wafer level package, the spacer and the wafer lens through the anodic bonding; and forming unit modules through a dicing process along a dicing line between the image sensors.

Herein, the wafer may be made of silicon or material containing the silicon and the transparent member may be made of material containing an alkali metal such as glass.

Further, the spacer may be made of the silicon or material containing the silicon and the wafer lens may be made of the material containing the alkali metal such as the glass.

Further, the anodic bonding may be performed at a temperature of less than 200° C. and at a voltage of 800V˜2,000V, wherein the voltage may be applied with different voltages in multi-steps.

And, in accordance with still another embodiment of the present invention to achieve the object, there is provided a method of manufacturing a wafer level camera module including the steps of: manufacturing a wafer level package by bonding a transparent member for sealing image sensors to an upper part of a wafer provided with the image sensors on a top surface through anodic bonding; bonding a spacer provided with windows to expose the image sensors to an upper part of the waver level package through the anodic bonding; bonding a wafer lens to an upper part of the spacer through the anodic bonding; and forming unit modules through a dicing process along a dicing line between the image sensors.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a structure of a wafer level camera module in accordance with an embodiment of the present invention; and

FIG. 2 to FIG. 7 are cross-sectional views sequentially illustrating a method of manufacturing a wafer level cameral module in accordance with another embodiment of the present invention.

### DETAILED DESCRIPTION OF THE PREFERRED EMBODIMENTS

Hereinafter, a matter regarding to an operation effect including a technical configuration to achieve the object of a wafer level camera module and a method of manufacturing the same in accordance with the present invention will be clearly appreciated through the following detailed description with reference to the accompanying drawings illustrating preferable embodiments of the present invention.

A Structure of a Wafer Level Camera Module

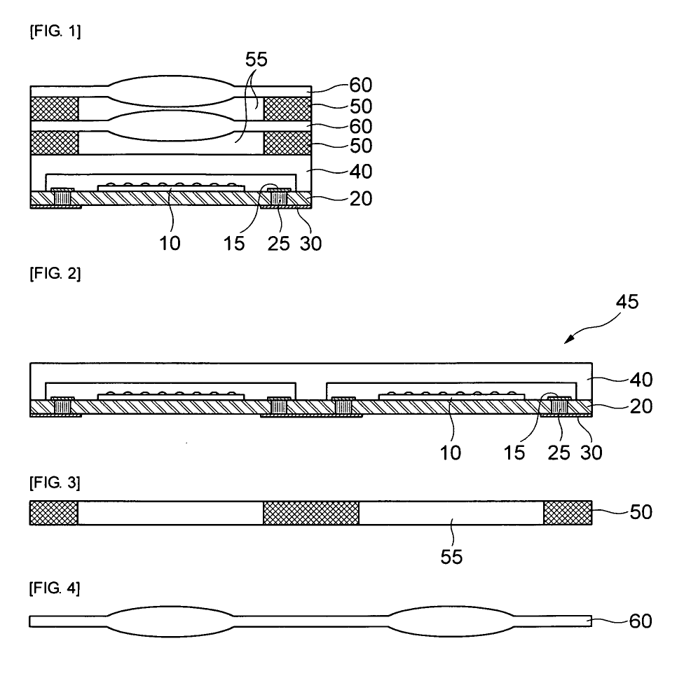

Hereinafter, a wafer level cameral module in accordance with an embodiment of the present invention will be described in detail with reference to FIG. 1.

FIG. 1 is a cross-sectional view showing a structure of a wafer level camera module in accordance with the embodiment of the present invention.

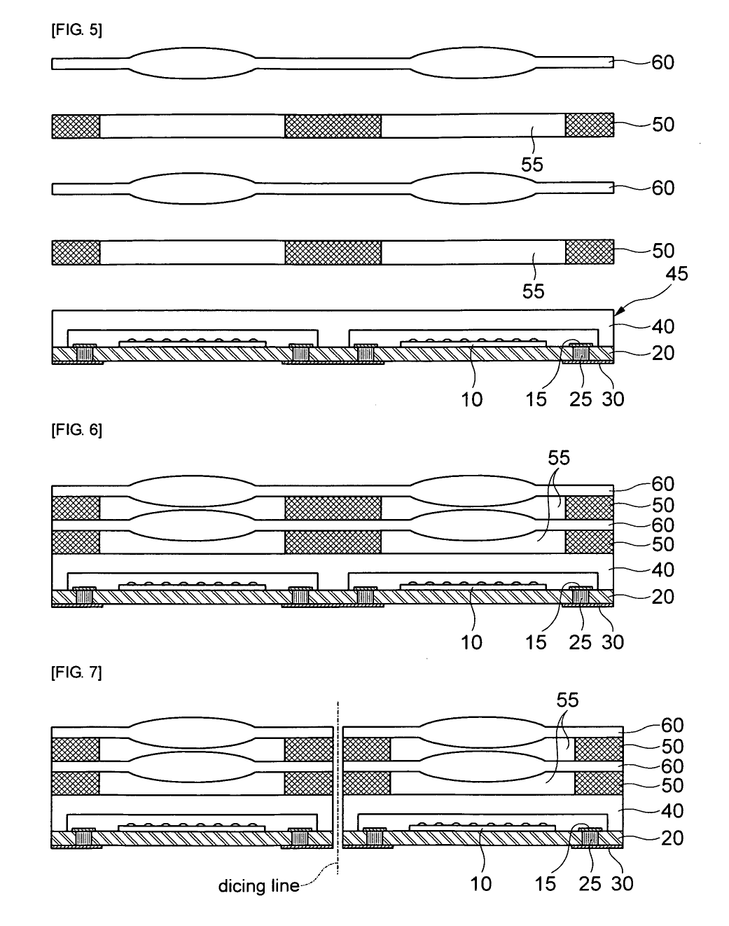

As shown in FIG. 1, in accordance with the embodiment of the present invention, a wafer level cameral module includes a wafer level package 45(referring to “45” in FIG. 2) in which a transparent member 40 is bonded to a wafer 20 provided with an image sensor 10 on a top surface through anodic bonding to seal the image sensor 10, a spacer 50 bonded to the transparent member 40 of the wafer level package 45 through the anodic bonding and a wafer lens 60 bonded to the spacer 50 through the anodic bonding.

The wafer 20 includes the image sensor 10 on the top surface and pads 15 outside both ends of the mage sensor 10 to interpose the image sensor 10

The wafer 20 includes wiring patterns 30 on a bottom surface, wherein the wiring patterns 30 are electrically connected to the pads 15 through vias 25 which are formed inside the wafer 20.

The wafer 20 may be made of silicon(Si), material containing the silicon or the like.

The transparent member 40 has a cavity space at a region corresponding to the image sensor 10 and is bonded to the wafer 20 through the anodic bonding to seal and protect the image sensor 10.

The transparent member 40 may be made of material containing an alkali metal such as glass.

On the wafer level package 40 constructed as described above, the spacer 50 provided with the window 55 to expose the image sensor 10 is bonded through the anodic bonding.

The spacer 50 may be made of the silicon, the material containing the silicon or the like similarly to the wafer 20.

And, on the spacer 50, the wafer lens 60 is bonded through the anodic bonding to cover the window 55 of the spacer.

The wafer lens 60 is manufactured in an array type by being molded in a wafer level state through a replica method, thereby reducing a manufacture cost of the lens.

At this time, the wafer lens 60 may include an iris(not shown) to block incidence of external light on the entire surface except an incidence hole which is formed at a central portion. The iris is preferably formed by a blackish coating film to prevent transmission of the external light.

The wafer lens 60 may be made of the material containing the alkali metal such as the glass similarly to the transparent member 40.

The wafer lens 60 may be formed by one sheet or two or more sheet of wafer lenses and, as described the above, each of the wafer lenses 60 may be stacked by being alternately bonded together with the spacer 150 through anodic bonding.

At this time, a height of the spacer 50 may be designed in consideration of a focal length of the lens which is determined between the wafer lens 60 and the image sensor 10 of a direct bottom portion thereof.

Therefore, the wafer lens 60 does not need an additional process for adjusting a focus because the adjustment of the focus is completed only by bonding the wafer lens 60 to the spacer 50.

As described above, in accordance with the embodiment of the present invention, the wafer level cameral module can improve thickness uniformity of a bonded portion by bonding the wafer 20 provided with the image sensor 10, the transparent member, the spacer 50 and the wafer lens 60 through the anodic bonding, thereby exactly maintaining the predetermined focal length between the waver lens 60 and the image sensor 10.

Further, when components constituting the wafer level cameral module are bonded through the anodic bonding, an additional bonding device for bonding therebetween is not needed.

Therefore, because the bonding device is not used, it is possible to prevent the image sensor 10, etc. from being contaminated due to bonding material and reduce material and process costs.

And, the material of the components bonded through the anodic bonding, that is, the silicon and the glass have little difference in a coefficient of thermal expansion, thereby preventing warpage due to a difference in the coefficient of thermal expansion.

A Method of Manufacturing a Wafer Level Camera Module

Hereinafter, a method of manufacturing a wafer level cameral module in accordance with another embodiment of the present invention will be described in detail with reference to FIG. 2. to FIG. 7.

FIG. 2 to FIG.7 are cross-sectional views sequentially illustrating a method of manufacturing a wafer level cameral module in accordance with another embodiment of the present invention.

First of all, as shown in FIG. 2, after preparing a wafer 20 which includes image sensors 10 and pads 15 on a top surface and vias 25 electrically connected to the pads 15 inside, a wafer level package 45 is manufactured by bonding a transparent member 40 for sealing the image sensors 10 to the wafer 20 through anodic bonding.

On a bottom surface of the wafer 20, wiring patterns 30 electrically connected to the vias 25 may be formed, wherein the wiring patterns 30 may be formed before or after bonding the transparent member 40 to the wafer 20.

As described above, the wafer 20 may be made of the silicon, the material containing the silicon or the like and the transparent member 40 may be made of the material containing the alkali metal such as the glass.

Then, as shown in FIG. 3, a spacer 50 provides with windows 55 at regions corresponding to the image sensors 10 provided on the wafer 20 is manufactured. The spacer 50 may be made of the silicon, the material containing the silicon or the like.

Further, a height of the spacer 50, as described above, may be designed in consideration of the focal length of the lens which is determined between the wafer lens 60 and the image sensor 10 of a direct bottom portion thereof.

At this time, the spacer may be prepared by being manufactured by one or more.

Then, as shown in FIG. 4, the wafer lens 60 is manufactured and prepared. The wafer lens 60 may be made of the material containing the alkali metal such as the glass similarly to the transparent member 40.

Further, the wafer lens 60 may be prepared by being manufactured by one or more similarly to the spacer 50.

Then, as shown in FIG. 5, the spacers 50 and the wafer lenses 60 are arranged on upper part of the wafer level package 45.

If the spacer 50 and the wafer lens 60 are prepared by one for each of them, they can be vertically arranged; whereas, if they are prepared by two or more, it is preferable that they are alternately arranged vertically.

Then, as shown in FIG. 6, the wafer level package 45, the spacers 50 and the wafer lenses 60 are bonded through the anodic bonding at the same time.

In the anodic bonding, when a temperature is risen to a predetermined temperature at a state of contacting the silicon with the glass and a voltage is applied by using a glass side as an anode and using a silicon side as a cathode, positive ions included in the glass are forcedly diffused to an anode side and a positive ion depletion layer is formed near a bonding interface with the silicon. In the positive ion depletion layer, negative ions are relatively rich and negative charges are accumulated and further, at the silicon side, static charges are accumulated to generate electrostatic attraction on the interface of the glass and the silicon, thereby bonding the glass and the silicon.

Particularly, in accordance with the embodiment of the present invention, the anodic bonding between the wafer level package 45, the spacers 50 and the wafer lenses 60 may be performed at a temperature of less than 200° C. and at a voltage of 800V˜2,000V.

That is to say, in accordance with the embodiment of the present invention, the anodic bonding is performed under the high voltage condition with the numerical value so that it is smoothly executed by attenuating deterioration of mobility of the ions even at a low temperature of less than 200° C.

At this time, the voltage may be separately applied with different voltages in multi-steps to increase a charge amount flowing in a substrate.

For example, the voltages may be applied through a first step of applying a voltage of approximately 800V, a second step of applying a voltage of approximately 1,350V and a third step of applying a voltage of approximately 2,000V.

As described above, in accordance with the embodiment of the present invention, because the anodic bonding can be performed even at the low temperature of less than 200° C. it is possible to prevent thermal deformation and damage of the image sensor, etc. due to a high temperature and because thickness uniformity of a bonded portion is very high, it is possible to exactly maintain the predetermined focal length between the wafer lens 60 and the image sensor 10.

Further, the module is manufactured by bonding the components at the same time, and therefore it is advantageous for mass production.

In addition, chemical resistance and an aging characteristic are improved at the bonded portion through the anodic bonding and therefore characteristic deterioration of the bonded portion is prevented, thereby enhancing reliability of the wafer level camera module.

Then, as shown in FIG. 7, unit modules are formed through a dicing process along a dicing line between the image sensors 10. The dicing process may be performed by a dicing blade, a laser or the like.

Meanwhile, in the method of manufacturing the wafer level camera module in accordance with the embodiment of the present invention, as described above, the wafer level package 45, the spacers 50 and the wafer lenses 60 are bonded through the anodic bonding at the same time, however, as a method of manufacturing the wafer level camera module in accordance with another embodiment of the present invention, a sequential bonding process may be performed to bond the wafer lens 60 to the spacer 50 through the anodic bonding after bonding the spacer 50 to the wafer level package 45 through the anodic bonding.

As described above, in accordance with the present invention, the wafer level camera module and the method of manufacturing the same are capable of exactly maintaining the predetermined focal length between the lens and the image sensor by improving the thickness uniformity of the bonded portion by bonding the wafer provided with the image sensor, the transparent member, the spacer and the wafer lens through the anodic bonding/

Further, the present invention is advantageous for mass production by bonding the components simultaneously to manufacture the module.

Further, the present invention has advantages of preventing the image sensor from being contaminated due to the bonding material and reducing the material and process costs without the additional bonding device.

As described above, although a few preferable embodiments of the present invention have been shown and described, it will be appreciated by those skilled in the art that substitutions, modifications and changes may be made in these embodiments without departing from the principles and spirit of the general inventive concept, the scope of which is defined in the appended claims and their equivalents.

1. A wafer level camera module comprising:
a wafer provided with an image sensor on a top surface;
a transparent member bonded to the wafer through anodic bonding to seal the image sensor;
a spacer bonded to the transparent member through the anodic bonding by including a window to expose the image sensor; and
a wafer lens bonded to the spacer through the anodic bonding to cover the window of the spacer.

2. The wafer level camera module of claim 1, wherein the wafer is made of silicon or material containing the silicon.

3. The wafer level camera module of claim 1, wherein the transparent member is made of material containing an alkali metal.

4. The wafer level camera module of claim 1, wherein the spacer is made of the silicon or material containing the silicon.

5. The wafer level camera module of claim 1, wherein the wafer lens is made of the material containing the alkali metal.

6. The wafer level camera module of claim 3, wherein the material containing the alkali metal is glass.

7. A method of manufacturing a wafer level camera module comprising:
manufacturing a wafer level package by bonding a transparent member for sealing image sensors to an upper part of a wafer provided with the image sensors on a top surface through anodic bonding;
positioning a spacer provided with windows to expose the image sensors on an upper part of the wafer level package;
positioning a wafer lens on an upper part of the spacer;
bonding the wafer level package, the spacer and the wafer lens through the anodic bonding; and
forming unit modules through a dicing process along a dicing line between the image sensors.

8. The method of claim 7, wherein the wafer is made of silicon or material containing the silicon.

9. The method of claim 7, wherein the transparent member is made of material containing an alkali metal.

10. The method of claim 7, wherein the spacer is made of the silicon or material containing the silicon.

11. The method of claim 7, wherein the wafer lens is made of the material containing the alkali metal.

12. The method of claim 9, wherein the material containing the alkali metal is glass.

13. The method of claim 7, wherein the anodic bonding is performed at a temperature of less than 200° C. and at a voltage of 800V˜2,000V.

14. The method of claim 13, wherein the voltage is applied with different voltages in multi-steps.

15. A method of manufacturing a wafer level camera module comprising:
manufacturing a wafer level package by bonding a transparent member for sealing image sensors to an upper part of a wafer provided with the image sensors on a top surface through anodic bonding;
bonding a spacer provided with windows to expose the image sensors to an upper part of the wafer level package through the anodic bonding;
bonding a wafer lens to an upper part of the spacer through the anodic bonding; and
forming unit modules through a dicing process along a dicing line between the image sensors.

16. The wafer level camera module of claim 5, wherein the material containing the alkali metal is glass.

17. The method of claim 11, wherein the material containing the alkali metal is glass.
